(19) United States
(12) Patent Application Publication
(10) Pub. No.: US 2012/0018897 A1
(43) Pub. Date: Jan. 26, 2012

(54) SEMICONDUCTOR MODULE AND METHOD OF MANUFACTURING THE SAME

(75) Inventors: Seung Wook Park, Gyunggi-do (KR); Young Do Kweon, Seoul (KR); Ju Pyo Hong, Gyunggi-do (KR)

(73) Assignee: SAMSUNG ELECTRO-MECHANICS CO., LTD., Gyunggi-do (KR)

(21) Appl. No.: 12/897,222

(22) Filed: Oct. 4, 2010

(30) Foreign Application Priority Data
Jul. 23, 2010 (KR) 1020100071506

(51) Int. Cl. H01L 23/48; H01L 21/50

(52) U.S. Cl. 257/774; 438/121; 257/E23.011; 257/E21.499

(57) ABSTRACT

Disclosed herein is a semiconductor module, including: a substrate including wiring patterns formed on both sides thereof; a first device mounted on the substrate; a first molding layer made of a molding material, surrounding the first device and including via holes formed therein to interconnect with the wiring pattern formed on one side of the substrate; and a second device mounted on the first molding layer and electrically connected with the wiring pattern formed on one side of the substrate through the via holes formed in the first molding layer.

### CROSS REFERENCE TO RELATED APPLICATION

This application claims the benefit of Korean Patent Application No. 10-2010-0071506, filed on Jul. 23, 2010, entitled “Semiconductor module and manufacturing method thereof”, which is hereby incorporated by reference in its entirety into this application.

### BACKGROUND OF THE INVENTION

1. Technical Field

The present invention relates to a semiconductor module and a method of manufacturing the same.

2. Description of the Related Art

With the advance of the electronic industry, the degree of integration of semiconductor integrated circuits (ICs) is rapidly increasing. In the beginning period in the field of mobile communications, portable devices limitedly provided services such as voice calls, short message transmission and the like, but, recently, they have gradually expanded their service from basic communication functions to multimedia functions such as games, data transmission, digital cameras, audio/video playing files and the like.

Meanwhile, in consideration of the portability of portable devices performing mobile communication functions, small-size and light-weight portable devices are essentially required.

In order to improve the degree of integration of circuit devices, a ball grid array (BGA) type packaging technology and a land grid array (LGA) type packaging technology have been used.

BGA type packaging technology is a technology of attaching a semiconductor integrated circuit-molded chip to a substrate using fused solder balls, and, in this case, the fused solder balls are used as input and output terminals of the semiconductor integrated circuit. In contrast, LGA type packaging technology is a packaging technology wherein the input and output terminals of the semiconductor integrated circuit use solder pads provided on the substrate without using the fused solder balls.

FIGS. 1 and 2 show a conventional shielding structure and packaging method.

FIG. 1 is a sectional view showing a BGA packaging method wherein a high-frequency module is manufactured by mounting an integrated circuit and a passive component 12 on a substrate 11 and then shielding the mounted integrated circuit and passive component 12 using a metal cap 14.

Here, when the metal cap 14 is thin, there is the problem that the strength of the metal cap 14 cannot be maintained, so that the metal cap 14 easily warps, with the result that the metal cap 14 comes into contact with a high-frequency semiconductor device. In order to prevent a short attributable to the contact of the metal cap 14 and the high-frequency semiconductor device, a predetermined space is required under the metal cap 14, considering that the metal cap 14 will warp. Due to this physical space, it is difficult to miniaturize the high-frequency module.

FIG. 2 is a sectional view showing a high-frequency module manufactured by molding a resin on a substrate and then performing a packaging process in a BGA packaging method.

Here, an integrated circuit and a passive component 12 are mounted on a substrate 11, and then a molding 15 is formed to cover the integrated circuit and the passive component 12. The molding 15 serves to protect the mounted integrated circuit and passive component 12 from the external environment or influences, and serves to strongly fix the mounted integrated circuit and passive component 12 on the substrate 11.

When the molding 15 is used, the physical space required is reduced compared to when the metal cap 14 is used, but it is also difficult to sufficiently reduce the physical space because the integrated circuit and the passive component 12 are simultaneously mounted on one side of the substrate.

### SUMMARY OF THE INVENTION

Accordingly, the present invention has been devised to solve the above-mentioned problems, and the present invention provides a semiconductor module which can become small and thin by providing interconnection to a molding layer, and a method of manufacturing the same.

Further, the present invention provides a semiconductor module which can improve its performance by providing interconnection to a molding layer to shorten a signal flow path, and a method of manufacturing the same.

An aspect of the present invention provides a semiconductor module, including: a substrate including wiring patterns formed on both sides thereof; a first device mounted on the substrate; a first molding layer made of a molding material, surrounding the first device and including via holes formed therein to interconnect with the wiring pattern formed on one side of the substrate; and a second device mounted on the first molding layer and electrically connected with the wiring pattern formed on one side of the substrate through the via holes formed in the first molding layer.

Here, the molding material constituting the first molding layer may be any one selected from an epoxy resin, a melamine derivative, a liquid crystal polymer, a polyphenylether (PPE) resin, a polyimide resin, a fluorine resin, a phenol resin, and polyamide bismaleimide.

Further, the semiconductor module may further include a second molding layer made of a molding material and surrounding the second device.

Further, the semiconductor module may further include a second molding layer made of a molding material and surrounding the first molding layer and the second device.

Further, the molding material constituting the second molding layer may be any one selected from an epoxy resin, a melamine derivative, a liquid crystal polymer, a polyphenylether (PPE) resin, a polyimide resin, a fluorine resin, a phenol resin, and polyamide bismaleimide.

Further, the semiconductor module may further include a cap surrounding the second device.

Further, the semiconductor module may further include a cap surrounding the first molding layer and the second device.

Further, each of the first device and the second device may include a semiconductor device and a passive device.

Another aspect of the present invention provides a method of manufacturing a semiconductor module, including: providing a substrate including wiring patterns formed on both sides thereof and then mounting a first device on the substrate; forming a first molding layer on the substrate mounted with the first device; forming via holes for interconnection in the first molding layer; and mounting a second device on the first molding layer to electrically connect the second device with the wiring pattern formed on one side of the substrate through the via holes.

Here, the first molding layer may be made of any one selected from an epoxy resin, a melamine derivative, a liquid crystal polymer, a polyphenylether (PPE) resin, a polyimide resin, a fluorine resin, a phenol resin, and polyamide bismaleimide.

Further, the method may further include: forming a second molding layer made of a molding material and surrounding the second device.

Further, the molding material constituting the second molding layer may be any one selected from an epoxy resin, a melamine derivative, a liquid crystal polymer, a polyphenylether (PPE) resin, a polyimide resin, a fluorine resin, a phenol resin, and polyamide bismaleimide.

Further, the method may further include: forming a second molding layer made of a molding material and surrounding the first molding layer and the second device.

Further, the method may further include: forming a cap surrounding the second device.

Further, the method may further include: forming a cap surrounding the first molding layer and the second device.

Further, the forming of the via holes may further include: forming holes in the first molding layer using laser; and filling the holes formed in the first molding layer with conductive paste to form the via holes.

### BRIEF DESCRIPTION OF THE DRAWINGS

The above and other objects, features and advantages of the present invention will be more clearly understood from the following detailed description taken in conjunction with the accompanying drawings, in which:

FIGS. 1 and 2 are sectional views showing a conventional shielding structure and packaging method.

FIG. 3 is a sectional view showing a semiconductor module according to a first embodiment of the present invention;

FIG. 4 is a sectional view showing a semiconductor module according to a second embodiment of the present invention;

FIG. 5 is a sectional view showing a semiconductor module according to a third embodiment of the present invention;

FIG. 6 is a sectional view showing a semiconductor module according to a fourth embodiment of the present invention;

FIGS. 7 to 15 are sectional views showing a method of manufacturing the semiconductor module according to a first embodiment of the present invention;

FIGS. 16 to 24 are sectional views showing a method of manufacturing the semiconductor module according to a second embodiment of the present invention;

FIGS. 25 to 33 are sectional views showing a method of manufacturing the semiconductor module according to a third embodiment of the present invention; and

FIGS. 34 to 42 are sectional views showing a method of manufacturing the semiconductor module according to a fourth embodiment of the present invention.

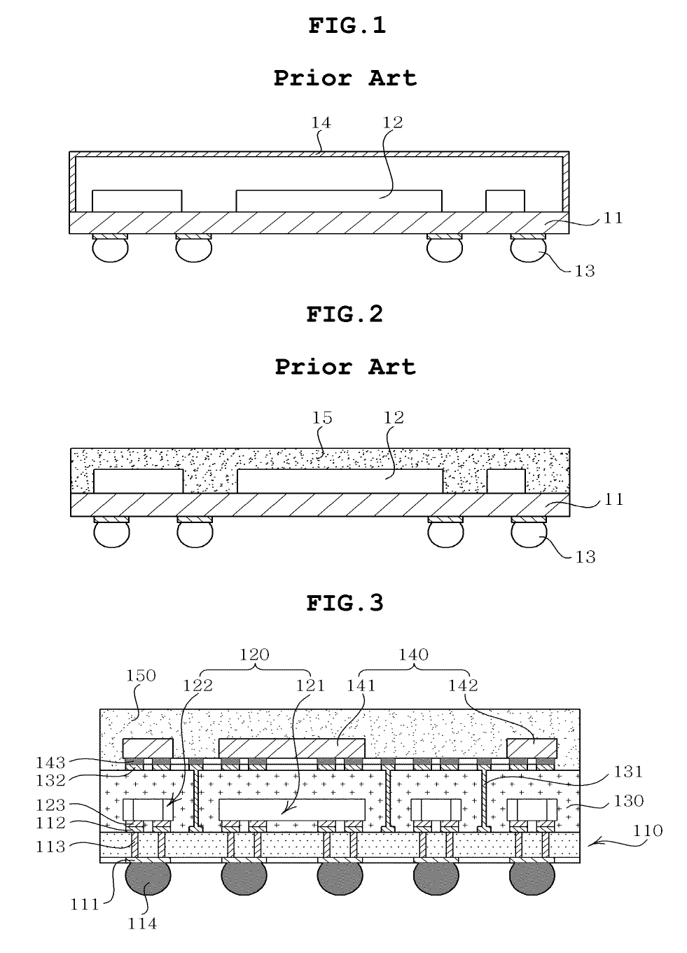

### DESCRIPTION OF THE PREFERRED EMBODIMENTS

The objects, features and advantages of the present invention will be more clearly understood from the following detailed description of preferred embodiments taken in conjunction with the accompanying drawings. Throughout the accompanying drawings, the same reference numerals are used to designate the same or similar components, and redundant descriptions thereof are omitted. Further, in the description of the present invention, when it is determined that the detailed description of the related art would obscure the gist of the present invention, the description thereof will be omitted.

Hereinafter, preferred embodiments of the present invention will be described in detail with reference to the attached drawings.

FIG. 3 is a sectional view showing a semiconductor module according to a first embodiment of the present invention.

Referring to FIG. 3, the semiconductor module according to the first embodiment of the present invention includes a substrate 110, a first device array 120 mounted on the substrate 110, a first molding layer 130 surrounding the first device array 120, a second device array 140 mounted on the first molding layer 130, and a second molding layer 150 surrounding the second device array 140.

Here, the substrate 110, which is a wiring substrate, includes a ceramic substrate, such as a high temperature co-fired ceramic (HTCC) substrate or a low temperature co-fired ceramic (LTCC) substrate, and a printed circuit board (PCB).

Further, the substrate 110 is formed on the surface thereof with a wiring pattern including pre-designed bonding pads 111 and bump pads 112, and is formed therein with via holes 113 or through-holes constituting the signal lines of the mounted device arrays 120 and 140.

Further, solder balls 114 are arranged on one side of the substrate 110 to be brought into contact with the bonding pads 111. Consequently, the semiconductor module may be mounted on a parent substrate through the solder balls 114.

Next, the first device array 120 mounted on the substrate 110 includes a semiconductor device 121 and a passive device 122. Examples of the semiconductor device 121 may include transistors, diodes, IC chips and the like, and examples of the passive device 122 may include chip condensers, chip resistors and the like.

The first device array 120 is provided on the underside thereof with bump pads 123, and the bump pads 123 are connected with the bump pads 112 provided on the upper side of the substrate 110 by flip-chip bonding. Of course, the first device array 120 and the substrate 110 may be connected to each other by wire bonding.

The first molding layer 130 is formed to surround the first device array 120, and may be made of any material as long as it is softened by heating.

For example, the first molding layer 130 may be made of an epoxy resin, a melamine derivative such as a bismaleimide triazine (BT) resin, a liquid crystal polymer, a polyphenylether (PPE) resin, a polyimide resin, a fluorine resin, a phenol resin, polyamide bismaleimide, or the like. When such a resin is used, a semiconductor module having excellent high-frequency characteristics and product reliability can be obtained.

Examples of the epoxy resin may include a bisphenol A type resin, a bisphenol F type resin, a bisphenol S type resin, a novolac type phenol resin, a novolac type cresol epoxy resin, a trisphenolmethane epoxy resin, an alicyclic epoxy resin, and the like.

Examples of the melamine derivative may include melamine, melamine cyanurate, methylolated melamine, (iso)cyanuric acid, succinoguanamine, melamine sulfate, guanamine acetate, guanylic melamine sulfate, a melamine resin, a bismaleimide triazine (BT) resin, cyanuric acid, isocyanuric acid and derivatives thereof, melamine isocyanurate, benzoguanamine, acetoguanamine, and the like.

Examples of the liquid crystal polymer may include aromatic liquid crystal polyester, liquid crystal polyimide, liquid crystal polyester amide, and resin compositions containing the same.

Further, the first molding layer 130 may include a filling material such as a filler or fiber. For example, particulate or fibrous SiO₂, SiN, AlN, Al₂O₃ or the like may be used as the filler. Since the first molding layer 130 includes a filler or fiber, it is possible to prevent the first molding layer 130 from warping when it cools to room temperature.

Therefore, the adhesion between the semiconductor device 121 and the first molding layer 130 and the adhesion between the passive device 122 and the first molding layer 130 can be made stronger. Further, when the first molding layer 130 includes a fiber, its fluidity can be increased, thus increasing the adhesion between the semiconductor device 121 and the first molding layer 130 and the adhesion between the passive device 122 and the first molding layer 130.

Further, the first molding layer 130 is provided therein with a plurality of via holes 131 through which the wiring pattern formed on the surface of the substrate 110 is electrically connected with the second device array 140 mounted on the first molding layer 130, and is provided thereon with a wiring pattern including bump pads 132 such that the second device array 140 can be mounted on the first molding layer 130.

That is, the second device array 140 is mounted on the first molding layer 130 by flip-chip bonding using bump pads 143 facing the bump pads 132 formed on the upper side of the first molding layer 130. Of course, the bump pads 132 formed on the upper side of the first molding layer 130 may be connected to the second device array 140 by wire bonding.

The first device array 140 also includes a semiconductor device 141 and a passive device 142. Examples of the semiconductor device 141 may include transistors, diodes, IC chips and the like, and examples of the passive device 142 may include chip condensers, chip resistors and the like.

Subsequently, the second molding layer 150 is formed to surround the second device array 140 mounted on the first molding layer 130, and is made of a molding material such as an epoxy resin, a melamine derivative such as a bismaleimide triazine (BT) resin, a liquid crystal polymer, a polyphenylether (PPE) resin, a polyimide resin, a fluorine resin, a phenol resin, polyamide bismaleimide or the like.

The second molding layer 150 may include a filling material such as a filler or fiber. Due to the second molding layer 150, the second device array 140 can be protected from external shocks or contamination.

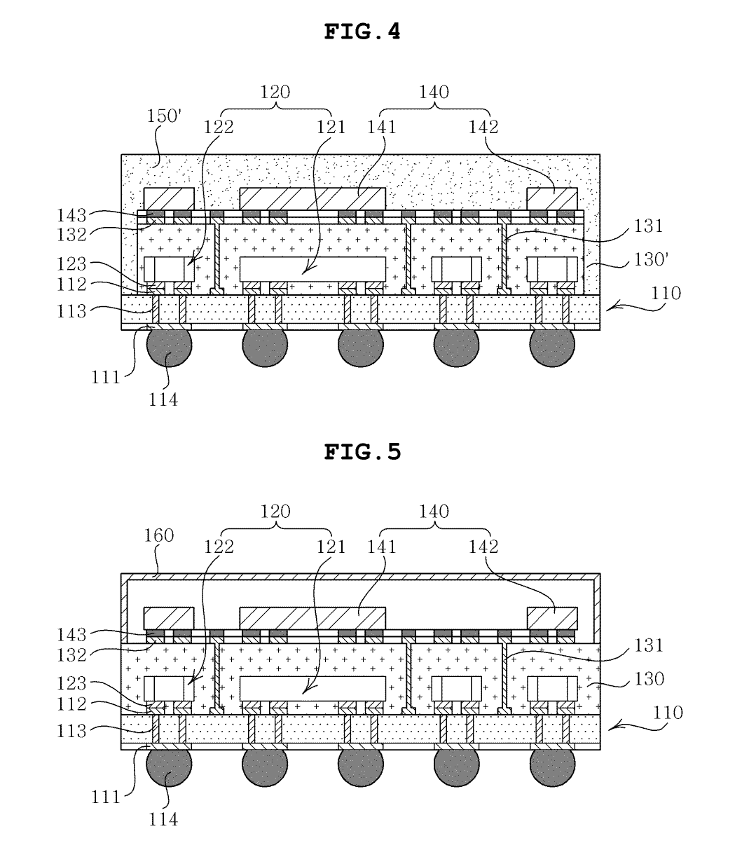

FIG. 4 is a sectional view showing a semiconductor module according to a second embodiment of the present invention.

The semiconductor module according to the second embodiment of FIG. 4 is different from the semiconductor module according to the first embodiment of FIG. 3 in that a second molding layer 150′ surrounds a first molding layer 130′ as well as a second device array 140.

In order to allow the second molding layer 150′ to surround the first molding layer 130′ as well as the second device array 140, the first molding layer 130′ is configured such that a substrate 110 is peripherally exposed, and the second molding layer 150′ is molded on the lateral surfaces of the first molding layer 130′ and the peripheral area of the substrate 10, thus protecting the exposed area of the substrate 110.

In this way, in the semiconductor module according to the second embodiment compared to the semiconductor module according to the first embodiment, the binding of the first molding layer 130′ and the second device array 140 can be enhanced, and the first device array 120 and the second device array 140 can be better protected because the second molding layer is integrally formed to surround both the first molding layer 130′ and the second device array 140. The detailed description of other components constituting the semiconductor module according to the second embodiment will be omitted because the components of the semiconductor module of the second embodiment are the same as those of the semiconductor module of the first embodiment.

FIG. 5 is a sectional view showing a semiconductor module according to a third embodiment of the present invention.

The semiconductor module according to the third embodiment of FIG. 5 is different from the semiconductor module according to the first embodiment of FIG. 3 in that a cap 160 is used to protect a second device array 140.

The cap 160 is formed to surround the second device array 140 which is a subject for providing electromagnetic wave shielding means. This cap 160 is made of a metal or a conductive material. The detailed description of other components constituting the semiconductor module according to the third embodiment will be omitted because the components of the semiconductor module of the third embodiment are the same as those of the semiconductor module of the first embodiment.

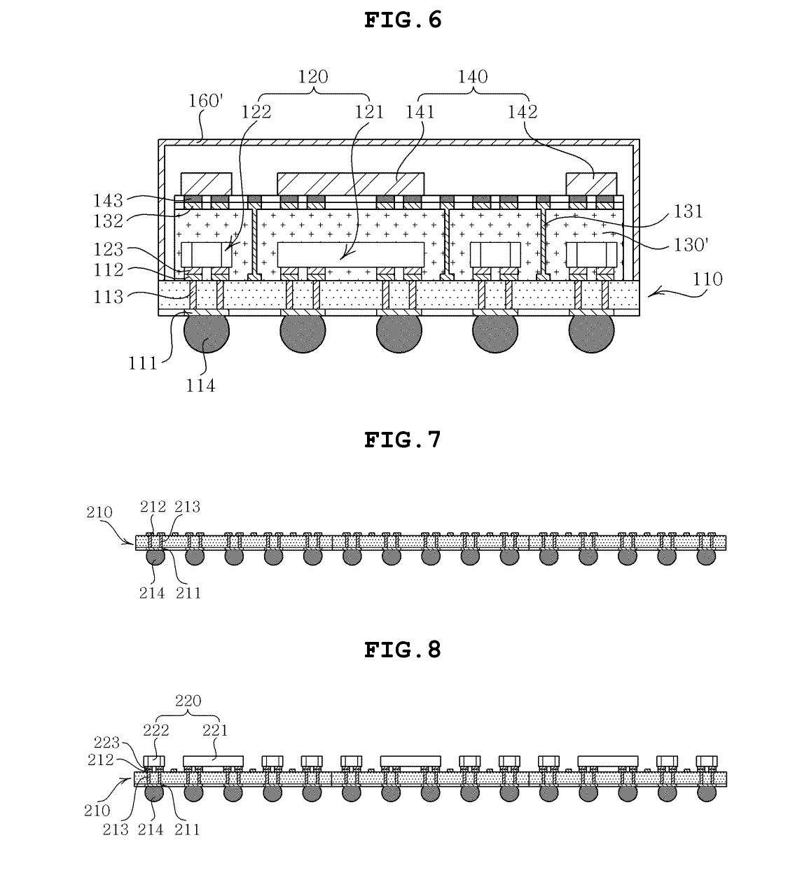

FIG. 6 is a sectional view showing a semiconductor module according to a fourth embodiment of the present invention.

The semiconductor module according to the fourth embodiment of FIG. 6 is different from the semiconductor module according to the third embodiment of FIG. 5 in that a cap 160′ surrounds a first molding layer 130′ as well as a second device array 140.

In order to allow the cap 160′ to surround the first molding layer 130′ as well as the second device array 140, the first molding layer 130′ is configured such that a substrate 110 is peripherally exposed and the cap 160′ is disposed on the substrate 110 thus protecting the exposed area of the substrate 110. The detailed description of other components constituting the semiconductor module according to the fourth embodiment will be omitted because the components of the semiconductor module of the fourth embodiment are the same as those of the semiconductor module of the first embodiment.

FIGS. 7 to 15 are sectional views showing a method of manufacturing the semiconductor module according to a first embodiment of the present invention.

First, as shown in FIG. 7, a substrate 210, which is a wiring substrate having a wiring pattern including pre-designed bonding pads 211 and bump pads 212 formed thereon and via holes 213 formed therein, is provided.

Further, solder balls 214 are arranged on one side of the substrate 210 to be brought into contact with the bonding pads 211. Consequently, the semiconductor module may be mounted on a parent substrate through the solder balls 214.

Subsequently, as shown in FIG. 8, a first device array 220 including a plurality of semiconductor devices 221 and passive devices 222 is mounted on the substrate 210.

Here, the first device array 220 may be mounted on the substrate 210 by flip-chip bonding or wire bonding (not shown).

Here, examples of the semiconductor device 221 may include transistors, diodes, IC chips and the like, and examples of the passive device 222 may include chip condensers, chip resistors and the like.

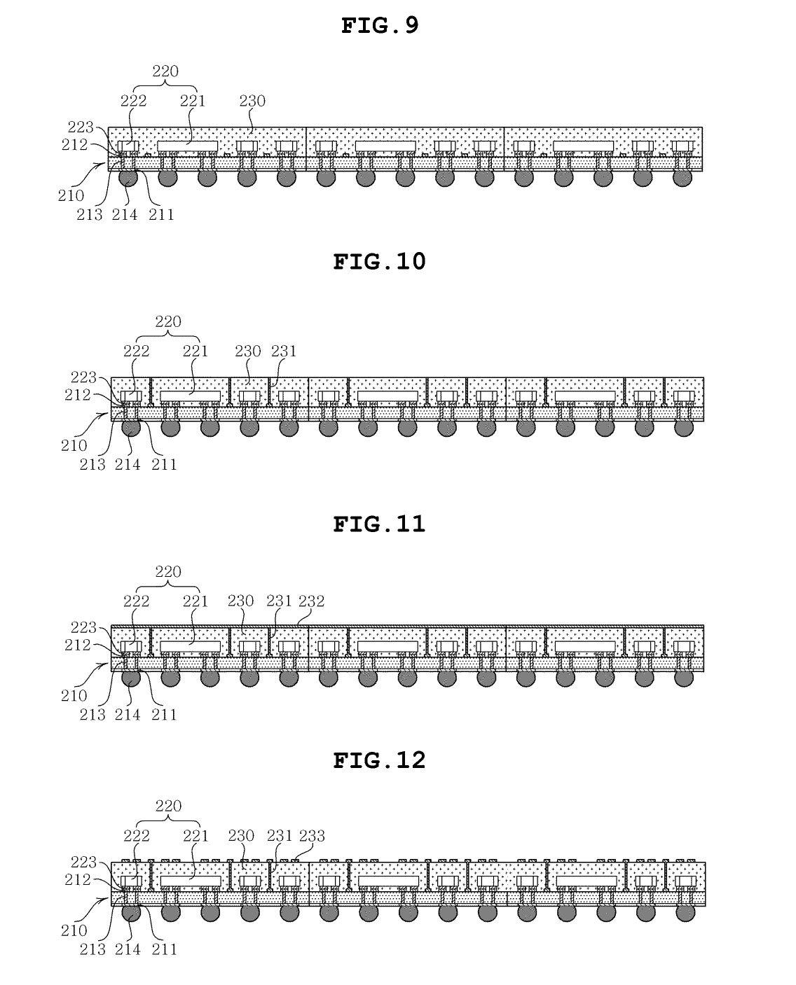

Subsequently, as shown in FIG. 9, a molding material is applied onto the substrate 210 with the plurality of semiconductor devices 221 and passive devices 222 fixed on the substrate 210 such that it surrounds the first device array 220, thus forming a first molding layer 230.

In this case, the first molding layer 230 may be formed using transfer molding, injection molding, potting or dipping, and examples of the molding material may include an epoxy resin, a melamine derivative such as a bismaleimide triazine (BT) resin, a liquid crystal polymer, a polyphenylether (PPE) resin, a polyimide resin, a fluorine resin, a phenol resin, polyamide bismaleimide and the like. Due to the use of this molding material, a semiconductor module having excellent high-frequency characteristics and product reliability can be obtained.

Further, the first molding layer 230 may include a filling material such as a filler or fiber.

Subsequently, as shown in FIG. 10, holes are formed in the first molding layer 130 using a laser, and then the holes are filled with a conductive material such as conductive paste or the like to via holes 231.

Subsequently, as shown in FIG. 11, a conductive layer 232 is formed on the first molding layer 230, and then, as shown in FIG. 12, the conductive layer 232 is patterned to provide electrical connections between the plurality of semiconductor devices 221 and passive devices 222, or the conductive layer 231 is formed into bump pads 233 to provide electrical connections between the semiconductor module and external terminals.

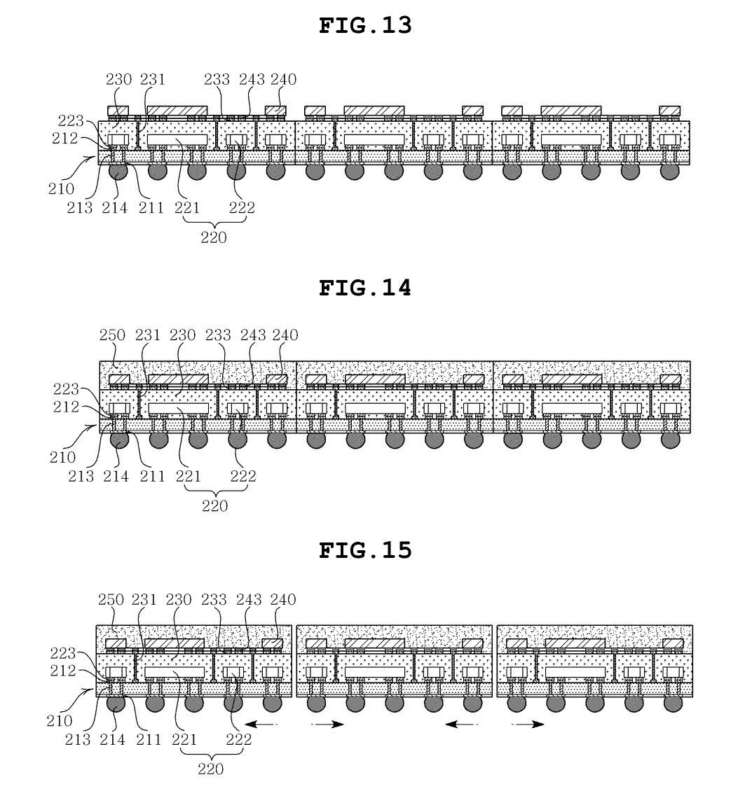

Subsequently, as shown in FIG. 13, a second device array 240 is mounted on the first molding layer 230 by bringing bump pads 243 formed on the underside of the second device array 240 into contact with the bump pads 233 formed on the first molding layer 230.

In this case, the second device array 240 mounted on the first molding layer 230 may include semiconductor devices, such as transistors, diodes, IC chips and the like, and passive devices such as chip condensers, chip resistors and the like.

Subsequently, as shown in FIG. 14, a second molding layer 250 made of a molding material such as an epoxy resin, a melamine derivative such as a bismaleimide triazine (BT) resin, a liquid crystal polymer, a polyphenylether (PPE) resin, a polyimide resin, a fluorine resin, a phenol resin, polyamide bismaleimide or the like is formed on the first molding layer 230 to protect the second device array 240 from the external.

Finally, as shown in FIG. 15, the product is diced using a cutter or laser to manufacture a plurality of semiconductor modules.

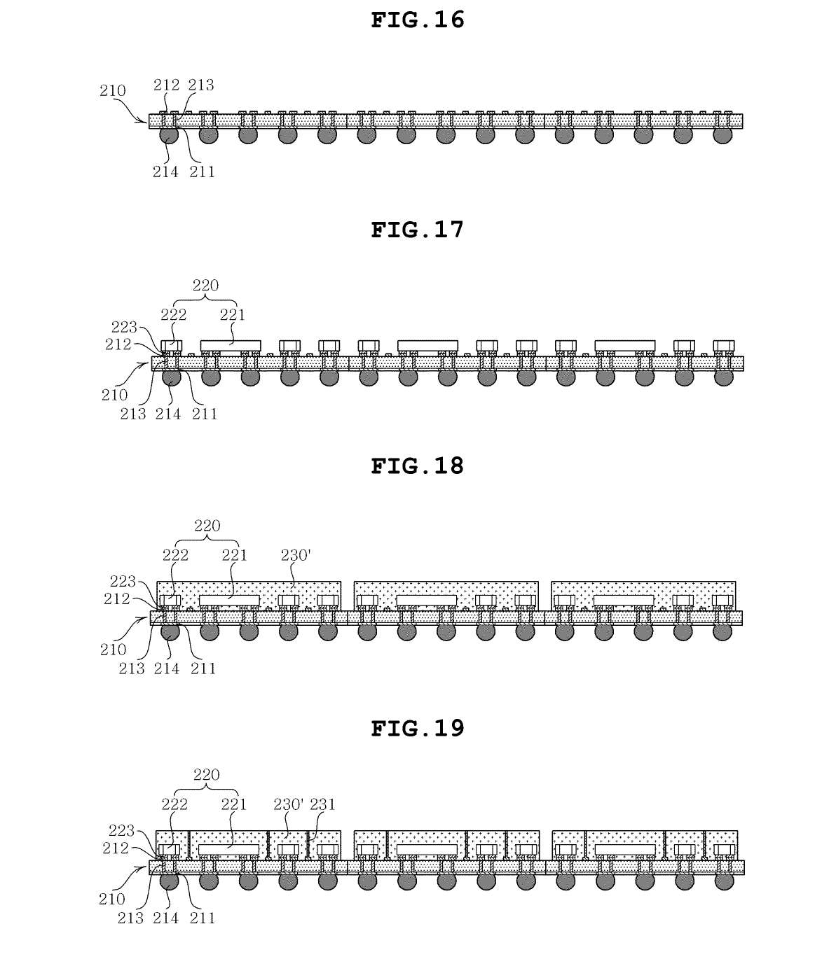

FIGS. 16 to 24 are sectional views showing a method of manufacturing the semiconductor module according to a second embodiment of the present invention.

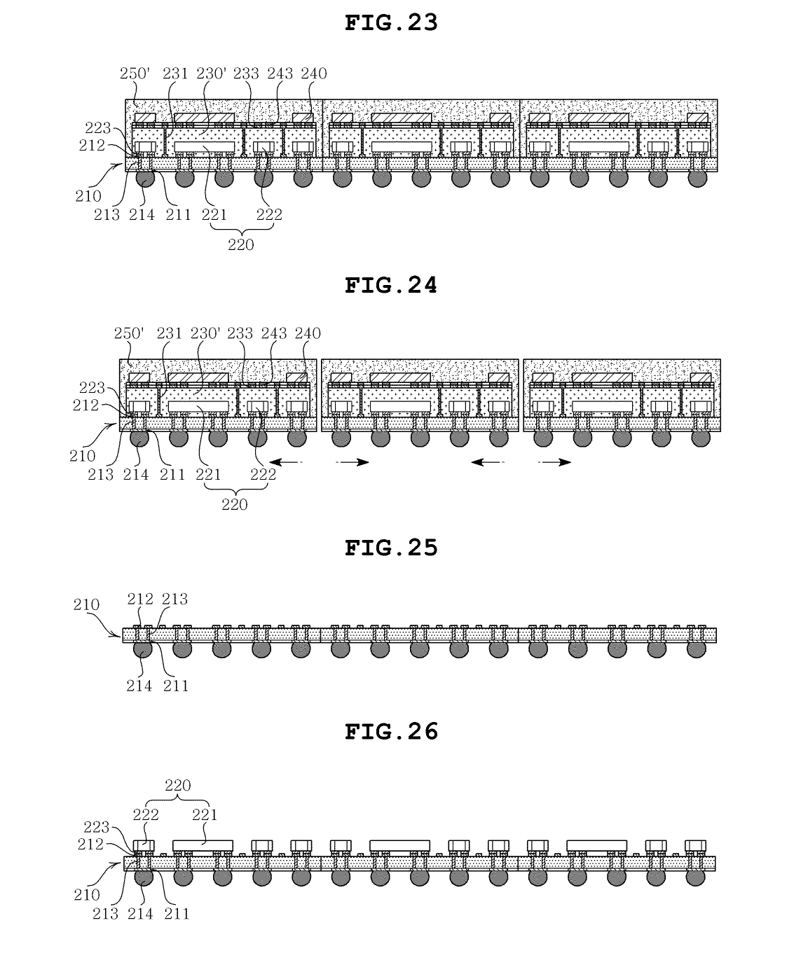

The method of manufacturing the semiconductor module according to the second embodiment of FIGS. 16 to 24 is different from the method of manufacturing the semiconductor module according to the first embodiment of FIGS. 7 to 15 in the point that, as shown in FIG. 18, a first molding layer 230′ is not completely formed on the substrate 210 to have removed regions therein, so that, as shown in FIG. 23, a second molding layer 250′ surrounds the first molding layer 230′ as well as the second device array 240.

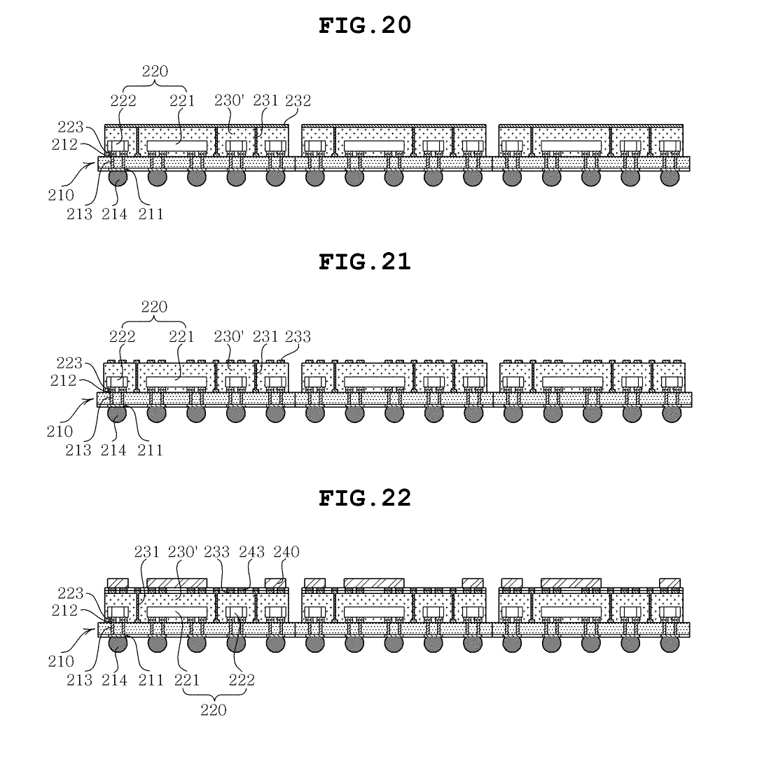

Other steps excluding the above steps, that is, the steps of providing a substrate 210 including pre-designed bonding pads 211, bump pads 212, via holes 213 and solder balls 214 (refer to FIG. 16), mounting a first device array 220 including a plurality of semiconductor device 221 and passive devices 222 on the substrate 210 (refer to FIG. 17), forming via holes 231 in a first molding layer 230′ (FIG. 19), forming a conductive layer 232 on the first molding layer 230′ (refer to FIG. 20), forming bump pads 233 (refer to FIG. 21), mounting a second device array 240 on the first molding layer 230′ by bringing bump pads 243 formed on the underside of the second device array 240 into contact with the bump pads 233 formed on the first molding layer 230′ (refer to FIG. 22), and dicing the product into a plurality of semiconductor modules (refer to FIG. 24) will not be described in detail because they are similar to those of the method of manufacturing the semiconductor module according to the first embodiment.

FIGS. 25 to 33 are sectional views showing a method of manufacturing the semiconductor module according to a third embodiment of the present invention.

The method of manufacturing the semiconductor module according to the third embodiment shown in FIGS. 25 to 33 is different from the method of manufacturing the semiconductor module according to the first embodiment of FIGS. 7 to 15 because a cap 260 is used to protect a second device array 240.

The cap 260 is formed to surround the second device array 240 which provides electromagnetic wave shielding means. This cap 260 is made of a metal or a conductive material.

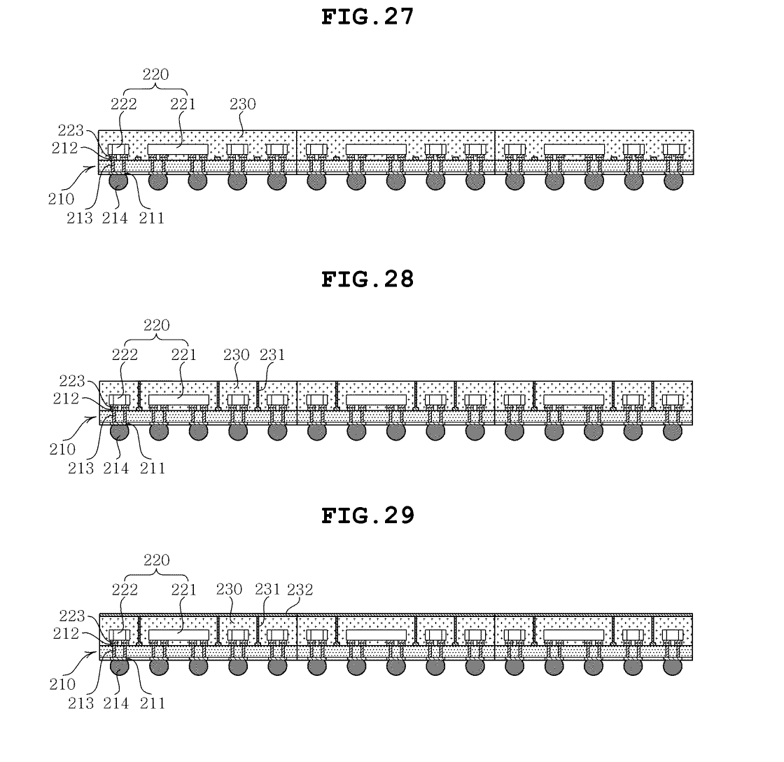

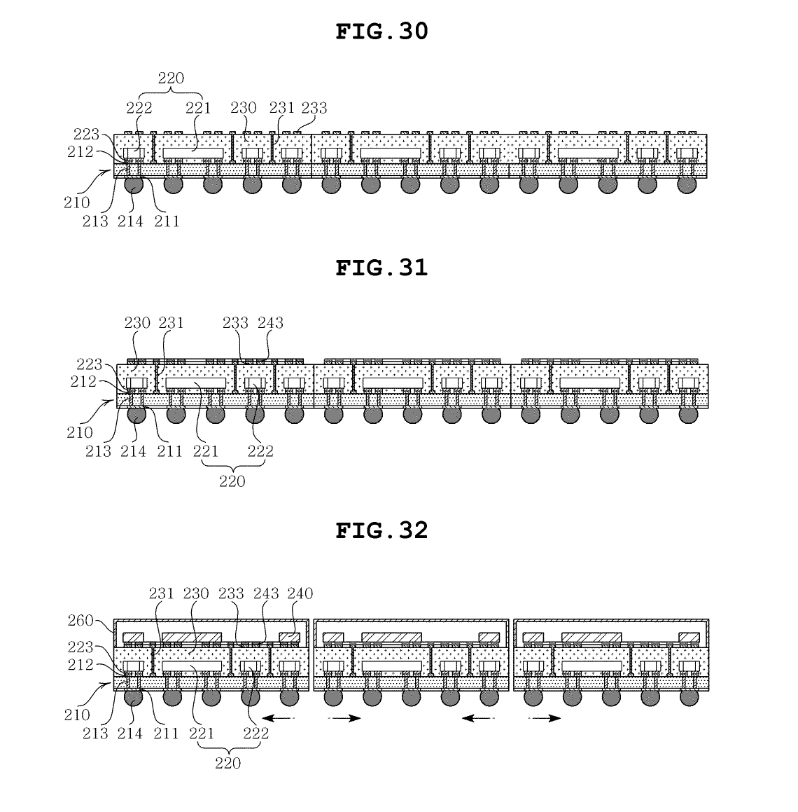

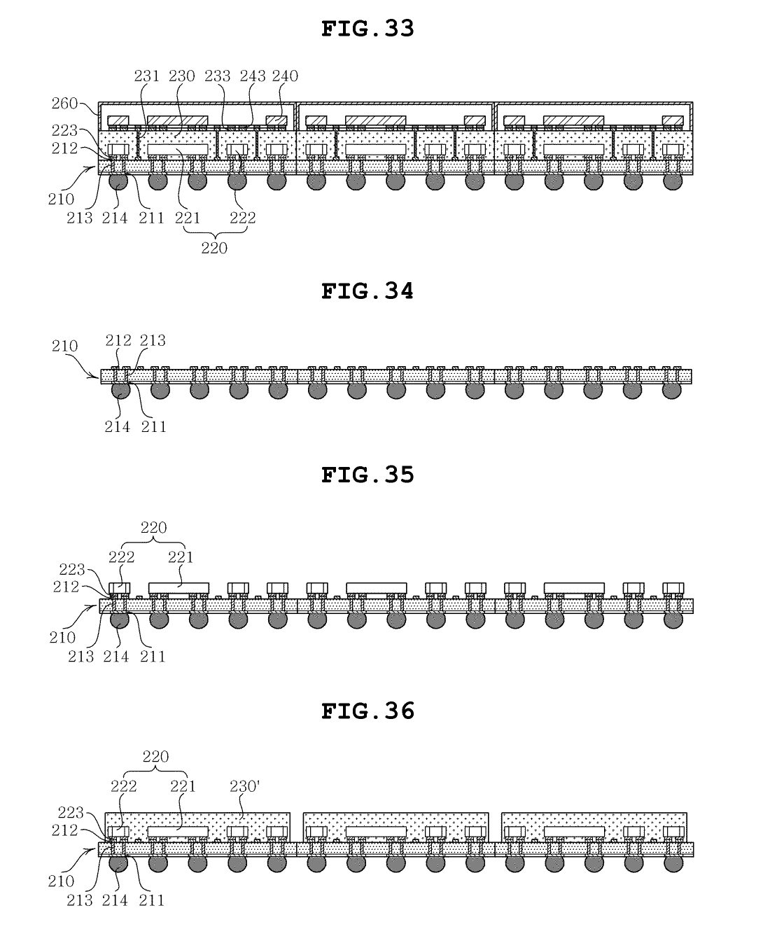

Other steps excluding the above steps, that is, the steps of providing a substrate 210 including pre-designed bonding pads 211, bump pads 212, via holes 213 and solder balls 214 (refer to FIG. 25), mounting a first device array 220 including a plurality of semiconductor device 221 and passive devices 222 on the substrate 210 (refer to FIG. 26), forming a first molding layer 230 by applying a molding material onto the substrate 210 with the plurality of semiconductor devices 221 and passive devices 222 fixed on the substrate 210 such that it surrounds the first device array 220 (refer to FIG. 27), forming via holes 231 in the first molding layer 230 (FIG. 28), forming a conductive layer 232 on the first molding layer 230 (refer to FIG. 29), forming bump pads 233 (refer to FIG. 30), mounting a second device array 240 on the first molding layer 230 by bringing bump pads 243 formed on the underside of the second device array 240 into contact with the bump pads 233 formed on the first molding layer 230 (refer to FIG. 31), and dicing the product into a plurality of semiconductor modules (refer to FIG. 33) will not be described in detail because they are similar to those of the method of manufacturing the semiconductor module according to the first embodiment.

FIGS. 34 to 42 are sectional views showing a method of manufacturing the semiconductor module according to the fourth embodiment of the present invention.

The method of manufacturing the semiconductor module according to the fourth embodiment shown in FIGS. 34 to 42 is different from the method of manufacturing the semiconductor module according to the third embodiment of FIGS. 25 to 33 because a cap 260′ surrounds a first molding layer 230′ as well as a second device array 240.

In order to allow the cap 260′ to surround the first molding layer 230′ as well as the second device array 240, as shown in FIG. 36, the first molding layer 230′ is formed on parts of the substrate 110, not on the entire substrate 210.

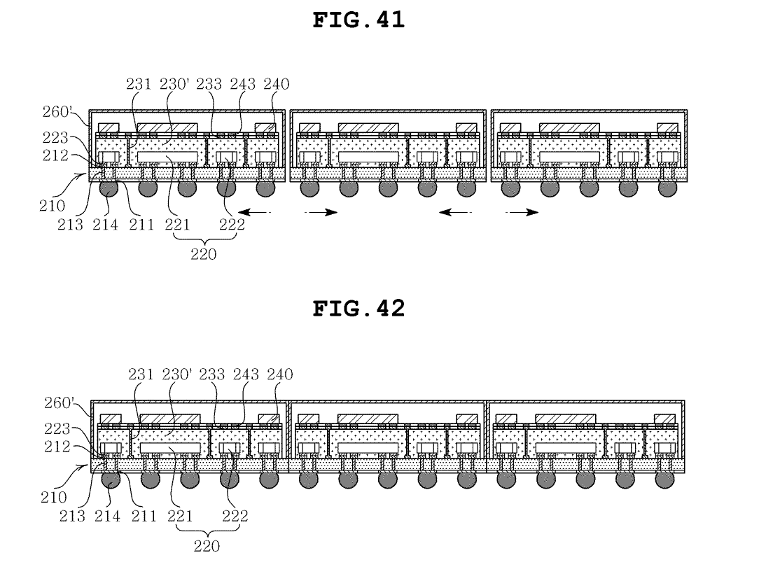

Further, as shown in FIG. 41, the cap 260′ is formed such that it surrounds both the first molding layer 230′ and the second device array 240.

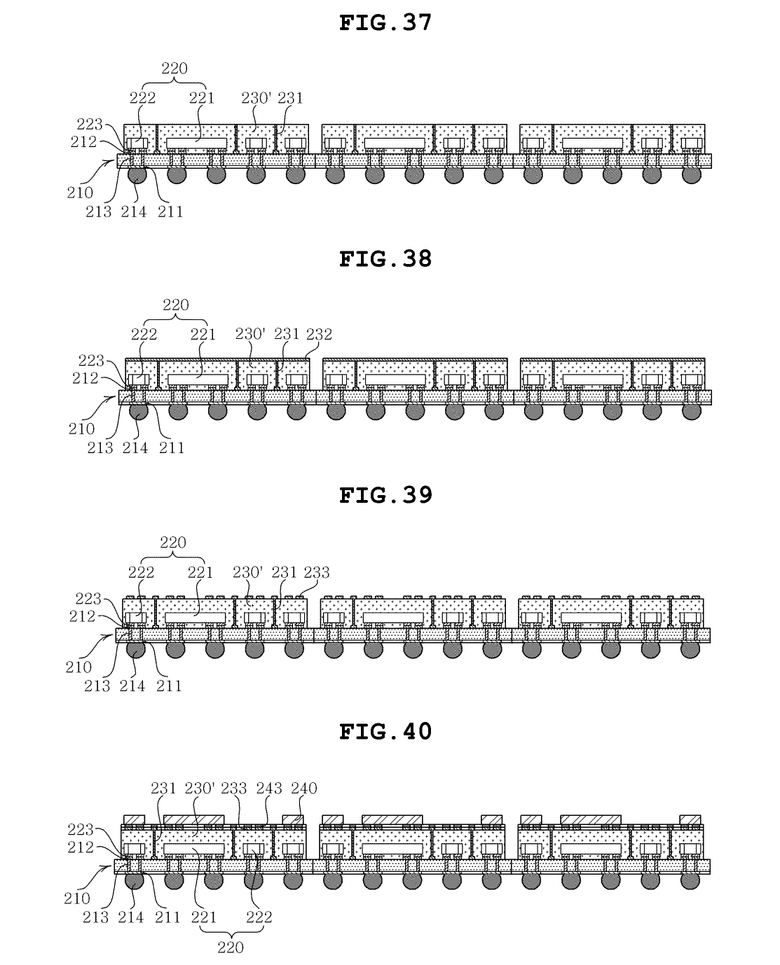

Other steps excluding the above steps, that is, the steps of providing a substrate 210 including pre-designed bonding pads 211, bump pads 212, via holes 213 and solder balls 214 (refer to FIG. 34), mounting a first device array 220 including a plurality of semiconductor device 221 and passive devices 222 on the substrate 210 (refer to FIG. 35), forming via holes 231 in a first molding layer 230′ (FIG. 37), forming a conductive layer 232 on the first molding layer 230′ (refer to FIG. 38), forming bump pads 233 (refer to FIG. 39), mounting a second device array 240 on the first molding layer 230′ (refer to FIG. 40), and dicing the product into a plurality of semiconductor modules (refer to FIG. 42) will not be described in detail because they are similar to those of the method of manufacturing the semiconductor module according to the third embodiment.

As described above, according to the present invention, a semiconductor module can become small and thin by providing molding layers with interconnections.

Further, according to the present invention, a high-performance semiconductor module can be realized by shortening the signal flow path between a first device array mounted in a first molding layer and a second device array mounted in a second molding layer.

The terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept of the term to describe the best method he or she knows for carrying out the invention.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

What is claimed is:

1. A semiconductor module, comprising:
a substrate including wiring patterns formed on both sides thereof;
a first device mounted on the substrate;
a first molding layer made of a molding material, surrounding the first device and including via holes formed therein to interconnect with the wiring pattern formed on one side of the substrate; and
a second device mounted on the first molding layer and electrically connected with the wiring pattern formed on one side of the substrate through the via holes formed in the first molding layer.

2. The semiconductor module according to claim 1, wherein the molding material constituting the first molding layer is any one selected from an epoxy resin, a melamine derivative, a liquid crystal polymer, a polyphenylether (PPE) resin, a polyimide resin, a fluorine resin, a phenol resin, and polyamide bismaleimide.

3. The semiconductor module according to claim 1, further comprising a second molding layer made of a molding material and surrounding the second device.

4. The semiconductor module according to claim 3, wherein the molding material constituting the second molding layer is any one selected from an epoxy resin, a melamine derivative, a liquid crystal polymer, a polyphenylether (PPE) resin, a polyimide resin, a fluorine resin, a phenol resin, and polyamide bismaleimide.

5. The semiconductor module according to claim 1, further comprising a second molding layer made of a molding material and surrounding the first molding layer and the second device.

6. The semiconductor module according to claim 5, wherein the molding material constituting the second molding layer is any one selected from an epoxy resin, a melamine derivative, a liquid crystal polymer, a polyphenylether (PPE) resin, a polyimide resin, a fluorine resin, a phenol resin, and polyamide bismaleimide.

7. The semiconductor module according to claim 1, further comprising a cap surrounding the second device.

8. The semiconductor module according to claim 1, further comprising a cap surrounding the first molding layer and the second device.

9. The semiconductor module according to claim 1, wherein the first device includes a semiconductor device and a passive device.

10. The semiconductor module according to claim 1, wherein the second device includes a semiconductor device and a passive device.

11. A method of manufacturing a semiconductor module, comprising:
providing a substrate including wiring patterns formed on both sides thereof and then mounting a first device on the substrate;
forming a first molding layer on the substrate mounted with the first device;
forming via holes for interconnection in the first molding layer; and
mounting a second device on the first molding layer to electrically connect the second device with the wiring pattern formed on one side of the substrate through the via holes.

12. The method according to claim 11, wherein the first molding layer is made of any one selected from an epoxy resin, a melamine derivative, a liquid crystal polymer, a polyphenylether (PPE) resin, a polyimide resin, a fluorine resin, a phenol resin, and polyamide bismaleimide.

12. The method according to claim 11, further comprising: forming a second molding layer made of a molding material and surrounding the second device.

14. The method according to claim 13, wherein the molding material constituting to the second molding layer is any one selected from an epoxy resin, a melamine derivative, a liquid crystal polymer, a polyphenylether (PPE) resin, a polyimide resin, a fluorine resin, a phenol resin, and polyamide bismaleimide.

15. The method according to claim 11, further comprising: forming a second molding layer made of a molding material and surrounding the first molding layer and the second device.

16. The method according to claim 15, wherein the molding material constituting the second molding layer is any one selected from an epoxy resin, a melamine derivative, a liquid crystal polymer, a polyphenylether (PPE) resin, a polyimide resin, a fluorine resin, a phenol resin, and polyamide bismaleimide.

17. The method according to claim 11, further comprising: forming a cap surrounding the second device.

18. The method according to claim 11, further comprising: forming a cap surrounding the first molding layer and the second device.

19. The method according to claim 11, wherein the forming of the via holes comprises: forming holes in the first molding layer using laser; and filling the holes formed in the first molding layer with conductive paste to form the via holes.
